(19) United States
(12) Patent Application Publication
(10) Pub. No.: US 2026/0029564 A1
(43) Pub. Date: Jan. 29, 2026

(54) DISPLAY PANEL AND DISPLAY DEVICE

(71) Applicant: WUHAN CHINA STAR OPTOELECTRONICS TECHNOLOGY CO., LTD., Wuhan, Hubei (CN)

(72) Inventors: Runfa ZONG, Wuhan, Hubei (CN); Yang YU, Wuhan, Hubei (CN); Qiang HE, Wuhan, Hubei (CN); Ruqing ZHANG, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/997,077

(22) PCT Filed: Jun. 28, 2023
(86) PCT No.: PCT/CN2023/103016

§ 371 Date: Jan. 18, 2025

(30) Foreign Application Priority Data
Mar. 31, 2023 (CN) 202310346267.5

(51) Int. Cl. G02B 5/26; H10D 86/40; H10D 86/60

(52) U.S. Cl. CPC G02B 5/26; H10D 86/451; H10D 86/60

(57) ABSTRACT

The present application provides display panel and a display device. The display panel includes a substrate, a buffer layer, a thin film transistor layer and an reflection-enhancing film group, where the reflection-enhancing film group includes one or more reflection-enhancing films, each reflection-enhancing film includes at least two reflection-enhancing layers, and a refractive index of a first reflection-enhancing layers away from the substrate is greater than a refractive index of a second reflection-enhancing layer close to the substrate.

### TECHNICAL FIELD

The present application relates to the field of display technology, and in particular, to a display panel and a display device.

### BACKGROUND

Low Temperature Poly-Silicon (LTPS) technology is becoming more and more widely used due to its advantages of ultra-thin, lightweight, and low power consumption. LTPS is sensitive to light, and when light from the bottom light source reaches the LTPS layer, it can cause the generation of photogenerated electrons in the LTPS, which will affect the LTPS thin film transistor (TFT) characteristics, leading to instability in the threshold voltage (Vₜₕ) and an increase in the off-state current (I_{off}).

As shown in FIG. 1, in the existing display panel 1, a light-shielding layer 30 is usually made on the bottom layer of the LTPS thin film transistor. The light-shielding layer 30 is located between the substrate 10 and the active layer 40, and the orthographic projection of the light-shielding layer 30 on the substrate 10 overlaps the orthographic projection of the active layer 40 on the substrate 10.

In actual applications, when Low Temperature Poly-Silicon is used in head-up display (HUD) technology and virtual reality (VR) technology, due to the facts that the brightness of its backlight (100000 nits˜200000 nit) is high, and that the existing light-shielding layer 30 is usually a thin metal layer, light still passes through the light-shielding layer in the exposure to intense light, leading to current leakage of the LTPS thin film transistor(s), thereby causing problems such as degradation of display performance.

### SUMMARY

Embodiments of the present application provide a display panel and a display device to alleviate the deficiencies in the related technology.

In order to realize the above functions, the embodiments of the present application provide the following technical solutions:
An embodiment of the present application provides a display panel, including:
a substrate;
a buffer layer located above the substrate;
a thin film transistor layer located on one side of the buffer layer away from the substrate, wherein the thin film transistor layer includes an active layer; and
a reflection-enhancing film group located on one side of the buffer layer away from the active layer, wherein an orthographic projection of the reflection-enhancing film group on the substrate overlaps an orthographic projection of the active layer on the substrate, the reflection-enhancing film group includes one or more reflection-enhancing films, each reflection-enhancing film includes at least two reflection-enhancing layers, and a refractive index of one of the reflection-enhancing layers away from the substrate is greater than a refractive index of another one of the reflection-enhancing layers close to the substrate;
wherein a thickness of each reflection-enhancing layer and wavelength of incident light satisfy the following equation:

$$2 {n}_{1} {h}_{1} + λ / 2 = k λ$$

where h₁ is the thickness of the reflection-enhancing layer, n₁ is a refractive index of corresponding dielectric layer of the reflection-enhancing layer, k is a positive integer, and λ represents the wavelength of the incident light.

In the display panel provided by the embodiments of the present application, the reflection-enhancing films included in the reflection-enhancing film group are stacked.

In the display panel provided by the embodiments of the present application, each reflection-enhancing film includes a plurality of first reflection-enhancing layers and a plurality of second reflection-enhancing layers, and the plurality of first reflection-enhancing layers and the plurality of second reflection-enhancing layers are alternately disposed along a direction from the substrate toward the active layer.

In the display panel provided by the embodiments of the present application, refractive indexes of the first reflection-enhancing layers located in different layers are the same or different, and/or refractive indexes of the second reflection-enhancing layers located in different layers are the same or different.

In the display panel provided by the embodiments of the present application, the refractive index of the second reflection-enhancing layer is less than the refractive index of a first reflection-enhancing layer that is in contact with either side of the second reflection-enhancing layer.

In the display panel provided by the embodiments of the present application, the reflection-enhancing film group is located between the substrate and the buffer layer, and the reflection-enhancing films included in the reflection-enhancing film group are a first reflection-enhancing film, a second reflection-enhancing film and a third reflection-enhancing film, wherein the first reflection-enhancing film reflects first color light, the second reflection-enhancing film reflects second color light, and the third reflection-enhancing film reflects third color light;
wherein color of the first color light, color of the second color light and color of the third color light are all different.

In the display panel provided by the embodiments of the present application, the first color light is blue light, the second color light is green light, and the third color light is red light; and
the thickness of the first reflection-enhancing layer of the first reflection-enhancing film ranges from 37 nanometers to 44 nanometers, and the thickness of the second reflection-enhancing layer of the first reflection-enhancing film ranges from 59 nanometers to 70 nanometers; the thickness of the first reflection-enhancing of in the second reflection-enhancing film ranges from 44 nanometers to 56 nanometers, and the thickness of the second reflection-enhancing layer of the second reflection-enhancing film ranges from 70 nanometers to 89 nanometers; and the thickness of the first reflection-enhancing layer of the third reflection-enhancing film ranges from 56 nanometers to 76 nanometers, and the thickness of the second reflection-enhancing layer of the third reflection-enhancing film ranges from 89 nanometers to 121 nanometers.

In the display panel provided by the embodiments of the present application, a reflectivity of the reflection-enhancing film group, a refractive index of the first reflection-enhancing layers, and a refractive index of the second reflection-enhancing layers satisfy the following equation:

$${R}_{1} = {( \frac{{n}_{0} - {( {n}_{H} / {n}_{L} )}^{2 k} ( {n}_{H}^{2} / {n}_{2} )}{{n}_{0} - {( {n}_{H} / {n}_{L} )}^{2 k} ( {n}_{H}^{2} / {n}_{2} )} )}^{2}$$

where R₁ is the reflectivity of the reflection-enhancing film group, no is refractive index of air, n_{H} is the refractive index of the first reflection-enhancing layers, n_{L} is the refractive index of the second reflection-enhancing layers, n₂ is refractive index of the substrate, 2 k is a total number of layers of the reflection-enhancing layers, and k is a natural number.

In the display panel provided by the embodiments of the present application, the reflection-enhancing film group is located on one side of the substrate away from the buffer layer.

In the display panel provided by the embodiments of the present application, a material of each reflection-enhancing film is one of titanium dioxide or zinc sulfide.

An embodiment of the present application provides a display device comprising a display panel, wherein the display panel includes:
a substrate;
a buffer layer located above the substrate;
a thin film transistor layer located on one side of the buffer layer away from the substrate, wherein the thin film transistor layer includes an active layer;
a reflection-enhancing film group located on one side of the buffer layer away from the active layer, wherein an orthographic projection of the reflection-enhancing film group on the substrate overlaps an orthographic projection of the active layer on the substrate, the reflection-enhancing film group includes one or more reflection-enhancing films, each reflection-enhancing film includes at least two reflection-enhancing layers, and a refractive index of one of the reflection-enhancing layers away from the substrate is greater than a refractive index of another one of the reflection-enhancing layers close to the substrate;
wherein, a thickness of each reflection-enhancing layer and wavelength of incident light satisfy the following equation:

$$2 {n}_{1} {h}_{1} + λ / 2 = k λ$$

where h₁ is the thickness of the reflection-enhancing layer, n₁ is refractive index of a corresponding dielectric layer of the reflection-enhancing layer, k is a positive integer, and λ represents the wavelength of the incident light.

In the display device provided by the embodiments of the present application, the reflection-enhancing films included in the reflection-enhancing film group are stacked.

In the display device provided by the embodiments of the present application, each reflection-enhancing film includes a plurality of first reflection-enhancing layers and a plurality of second reflection-enhancing layers, and the plurality of first reflection-enhancing layers and the plurality of second reflection-enhancing layers are alternately disposed along a direction from the substrate toward the active layer.

In the display device provided by the embodiments of the present application, refractive indexes of the first reflection-enhancing layers located in different layers are the same or different, and/or refractive indexes of the second reflection-enhancing layers located in different layers are the same or different.

In the display device provided by the embodiments of the present application, the refractive index of the second reflection-enhancing layer is less than the refractive index of a first reflection-enhancing layer that is in contact with either side of the second reflection-enhancing layer among of the plurality of first reflection-enhancing layers.

In the display device provided by the embodiments of the present application, the reflection-enhancing film group is located between the substrate and the buffer layer, and the reflection-enhancing films included in the reflection-enhancing film group are a first reflection-enhancing film, a second reflection-enhancing film and a third reflection-enhancing film, wherein the first reflection-enhancing film reflects first color light, the second reflection-enhancing film reflects second color light, and the third reflection-enhancing film reflects third color light;

Wherein a color of the first color light, color of the second color light, and a color of the third color light are all different.

In the display device provided by the embodiments of the present application, the first color light is blue light, the second color light is green light, and the third color light is red light; and
the thickness of the first reflection-enhancing layer of the first reflection-enhancing film ranges from 37 nanometers to 44 nanometers, and the thickness of the second reflection-enhancing layer of the first reflection-enhancing film ranges from 59 nanometers to 70 nanometers; the thickness of the first reflection-enhancing layer of the second reflection-enhancing film ranges from 44 nanometers to 56 nanometers, and the thickness of the second reflection-enhancing layer of the second reflection-enhancing film ranges from 70 nanometers to 89 nanometers; and the thickness of the first reflection-enhancing layer of the third reflection-enhancing film ranges from 56 nanometers to 76 nanometers, and the thickness of the second reflection-enhancing layer of the third reflection-enhancing film ranges from 89 nanometers to 121 nanometers.

In the display device provided by the embodiments of the present application, a reflectivity of the reflection-enhancing film group, a refractive index of the first reflection-enhancing layers, and a refractive index of the second reflection-enhancing layers satisfy the following equation:

$${R}_{1} = {( \frac{{n}_{0} - {( {n}_{H} / {n}_{L} )}^{2 k} ( {n}_{H}^{2} / {n}_{2} )}{{n}_{0} - {( {n}_{H} / {n}_{L} )}^{2 k} ( {n}_{H}^{2} / {n}_{2} )} )}^{2}$$

where R₁ is the reflectivity of the reflection-enhancing film group, no is a refractive index of air, n_{H} is the refractive index of the first reflection-enhancing layers, n_{L} is the refractive index of the second reflection-enhancing layers, n₂ is a refractive index of the substrate, 2 k is a total number of layers of the reflection-enhancing layers, and k is a natural number.

In the display device provided by the embodiments of the present application, the reflection-enhancing film group is located on one side of the substrate away from the buffer layer.

In the display device provided by the embodiments of the present application, wherein a material of each reflection-enhancing film is one of titanium dioxide or zinc sulfide.

### Beneficial Effect

Embodiments of the present application provide a display panel and a display device. The display panel includes a substrate, a buffer layer, a thin film transistor layer and a reflection-enhancing film group, which are stacked. The thin film transistor layer includes an active layer. The reflection-enhancing film group is located on a side of the buffer layer away from the active layer. An orthographic projection of the reflection-enhancing film group on the substrate overlaps an orthographic projection of the active layer on the substrate. The reflection-enhancing film group includes one or more reflection-enhancing films. Each reflection-enhancing film includes at least two reflection-enhancing layers, and a refractive index of the reflection-enhancing layer away from the substrate is greater than a refractive index of another reflection-enhancing layer close to the substrate. The reflection-enhancing film group includes a reflection-enhancing film, wherein a thickness of the reflection-enhancing film and a wavelength of the incident light satisfy the following equation: 2n₁h₁+λ/2=kλ, where h₁ is the thickness of the reflection-enhancing layer, n₁ is a refractive index of a corresponding dielectric layer, k is a positive integer, and λ represents the wavelength of the incident light. According to the principle of coherent enhancement, the thickness h₁ of the reflection-enhancing film is controlled to be the minimum value h₁=λ/4n (when k=1), and two beams of reflected light reflected by the upper surface and the lower surface of the reflection-enhancing film are coherent and constructively interfere, so that the light waves mutually superpose, thereby increasing the energy of the light reflected by the reflection-enhancing film, and enhancing the reflectivity of the reflection-enhancing film, thereby reducing the intensity of light irradiating the active layer and reducing the impact of light on the thin film transistors.

### BRIEF DESCRIPTION OF THE DRAWINGS

The technical solutions and other beneficial effects of the present application will be apparent through a detailed description of the specific embodiments of the present application in conjunction with the accompanying drawings.

FIG. 1 is a schematic structural diagram of an existing display panel;

FIG. 2 is a schematic diagram showing a first structure of a display panel provided by an embodiment of the present application;

FIG. 3 is a schematic diagram showing a second structure of a display panel provided by an embodiment of the present application;

FIG. 4 is a schematic diagram showing a third structure of a display panel provided by an embodiment of the present application;

FIG. 5 is a schematic diagram showing a fourth structure of a display panel provided by an embodiment of the present application;

FIG. 6 is a flow chart of a method for manufacturing a display panel provided by an embodiment of the present application; and

FIGS. 7A to 7B are structural process flow diagrams showing the manufacturing of the display panel in FIG. 6.

### DETAILED DESCRIPTION

The technical solutions in the embodiments of the present application will be clearly and completely described below with reference to the accompanying drawings in the embodiments of the present application. It is evident that the described embodiments are only some of the embodiments of the present application, rather than all of the embodiments. Based on the embodiments in the present application, all other embodiments obtained by a person skilled in the art without creative labor fall within the scope of protection of the present application.

Embodiments of the present application provide a display panel and a display panel. Each of these is described in detail below. It should be noted that the following embodiments are described in an order which is not taken as a limitation on the preferred order of embodiments.

Please refer to FIG. 2, which is a schematic diagram showing a first structure of a display panel provided by an embodiment of the present application.

In this embodiment, a display panel 2 is provided according to an embodiment of the present application. The display panel 2 includes a substrate 10, a buffer layer 20, a thin film transistor layer 100, and a reflection-enhancing film group 70, which are stacked. The thin film transistor layer 100 includes an active layer 40. The reflection-enhancing film group 70 is located on a side of the buffer layer 20 away from the active layer 40. An orthographic projection of the reflection-enhancing film group 70 on the substrate 40 overlaps an orthographic projection of the active layer 40 on the substrate 10. The reflection-enhancing film group 70 includes one or more reflection-enhancing films 71. Each reflection-enhancing film 71 includes at least two reflection-enhancing layers 710, and a refractive index of the reflection-enhancing layer 710 far away from the substrate 10 is greater than a refractive index of the other reflection-enhancing layer 710 close to the substrate 10.

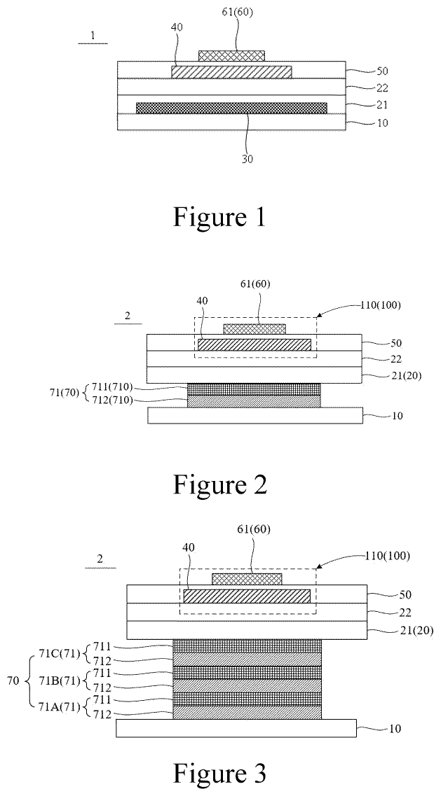

Please refer to FIGS. 1 and 2, where FIG. 1 is a schematic diagram of the structure of an existing display panel. It should be noted that in the prior art, the light-shielding layer 30 can shied the light directed to the active layer 40, thereby reducing the increase in leakage current caused by the photogenerated carriers generated by light irradiation onto the active layer 40, and thus to maintain the stability of the existing display panel 1 when working. However, in the prior art, the material of the shielding layer 30 is usually one or more alloys of molybdenum (Mo), titanium (Ti), and nickel (Ni). When static electricity is generated externally or when an electrostatic gun is used to conduct an electrostatic test, the static electricity generated externally or by the electrostatic gun can enter the thin film transistor through the “metal light-shielding layer 30”, thereby damaging the thin film transistor and causing the problem of electrostatic discharge (ESD) in the existing display panel 1.

It can be understood that, in the embodiment, the reflection-enhancing film group is located on one side of the buffer layer away from the active layer, and the orthographic projection of the reflection-enhancing film group on the substrate overlaps the orthographic projection of the active layer on the substrate. The reflection-enhancing film group includes at least one or more reflection-enhancing films. Each reflection-enhancing film includes at least two reflection-enhancing layers, and the refractive index of a reflection-enhancing layer 710 away from the substrate 10 is greater than the refractive index of the other reflection-enhancing layer 710 close to the substrate 10. The reflection-enhancing film group is used to replace the metal light-shielding layer in the prior art, avoiding the problem of electrostatic discharge (ESD) in existing display panels caused by the “metal light-shielding layer”.

In the actual manufacturing process, when the incident light is a waveband light, such as white light, blue light, red light or green light, the wavelength value corresponding to the wave peak in the corresponding waveband light is selected as the wavelength of the incident light, and the obtained reflection-enhancing layer thickness is a specific value, while the corresponding reflection-enhancing layer has the highest reflectivity.

In this embodiment, the substrate 10 may be a rigid substrate or flexible substrate. When the substrate 10 is a rigid substrate, the material may be metal or glass. When the substrate 10 is a flexible substrate, the material may include at least one of acrylic resin, methacrylic resin, polyisoprene, vinyl resin, epoxy-based resin, polyurethane-based resin, cellulose resin, silicone resin, polyimide-based resin, and polyamide-based resin. In this embodiment, the substrate 10 being a glass substrate is taken as an example to illustrate the technical solution of the present application.

The material of the buffer layer 20 includes but is not limited to a single layer of silicon nitride (Si₃N₄), a single layer of silicon dioxide (SiO₂), a single layer of silicon oxynitride (SiON_{X}), or a double-layer structure of the above layers. Specifically, the buffer layer 20 has a double-layer structure, and the buffer layer 20 includes a first buffer layer 21 and a second buffer layer 22. The second buffer layer 22 is located on a side of the first buffer layer 21 away from the reflection-enhancing film group 70. The first buffer layer 21 is in direct contact with the reflection-enhancing film group 70.

The thin film transistor layer 100 includes an active layer 40 located on the substrate 10, a gate insulating layer 50, a first metal layer 60, an interlayer insulating layer (not shown in the figure), and a second metal layer (not shown in the figure). The active layer 40 includes a first conductor portion (not shown in the figure), a second conductor portion (not shown in the figure), and an active section (not marked in the figure) between the first conductor portion and the second conductor portion. The first metal layer 60 includes a gate 61, and the gate 61 corresponds to the active section. The second metal layer includes a source (not shown in the figure) and a drain (not shown in the figure) arranged at an interval. The source is connected to the first conductor portion, and the drain is connected to the second conductor portion. The gate insulating layer 50 is located between the active layer 40 and the gate 61, and the material of the gate insulating layer 50 includes but is not limited to silicon oxide (SiO_{X}).

It should be noted that, in this embodiment, the thin film transistor layer 100 includes at least one thin film transistor 110. The thin film transistor 110 includes the active layer 40, the gate insulating layer 50, the gate 61, the interlayer insulating layer, the source and the drain, which are stacked sequentially on the substrate 10. In this embodiment, the thin film transistor is a Low Temperature Poly-Silicon (LTPS) thin film transistor and the active layer is a polysilicon layer, which are taken as an example to illustrate the technical solution of the present application.

Specifically, in this embodiment, the reflection-enhancing film group 70 is located between the substrate 10 and the buffer layer 20. The reflection-enhancing film group 70 includes an reflection-enhancing film 71. The reflection-enhancing film 71 includes a first reflection-enhancing layer 711 and a second reflection-enhancing layer 712. The refractive index n_{H} of the first reflection-enhancing layer 711 is greater than the refractive index n of the second reflection-enhancing layer 712. The first reflection-enhancing layer 711 is located on the side of the second reflection-enhancing layer 712 away from the substrate 10.

Herein, the thickness of each reflection-enhancing layer 710 and the wavelength of the incident light satisfy the following equation:

$$2 {n}_{1} {h}_{1} + λ / 2 = k λ , \qquad ( 1 )$$

where h₁ is the thickness of the reflection-enhancing layer 710, n₁ is the refractive index of the corresponding dielectric layer, k is a positive integer, and λ represents the wavelength of the incident light. It should be noted that in this embodiment, the technical solution of the present application is illustrated with an example of the reflection-enhancing film group 70 including one reflection-enhancing film 71. When the reflection-enhancing film group 70 includes one reflection-enhancing film 71, the incident light includes but is not limited to one or more of red light, green light, and blue light.

It should be noted that, in actual applications, when Low Temperature Poly-Silicon is used in head-up display (HUD) technology and virtual reality (VR) technology, due to the facts that the brightness of its backlight (100000 nits˜200000 nit) is high, and that the existing light-shielding layer 30 is usually a thin metal layer, light still passes through the light-shielding layer in the exposure to intense light, leading to current leakage of the LTPS thin film transistors, thereby causing problems such as degradation of display performance.

It can be understood that according to the principle of coherence enhancement, when light is incident from a denser medium to a less dense medium, no phase change will occur for the reflected light. When light is incident from a less dense medium to a denser medium and is reflected at the interface, the reflected light will produce a half-wave loss. In this embodiment, when light enters the reflection-enhancing film 71, the optical path difference d between the two reflected lights reflected by the upper surface and the lower surface of the reflection-enhancing film 71 satisfy the equation: d=2n₁h₁+λ/2=kλ. Therefore, in this embodiment, the thickness h₁ of the reflection-enhancing film can be controlled to be the minimum value h₁=λ/4n (when k=1). When light enters the reflection-enhancing film 71, the two beams of reflected light reflected by the upper surface and the lower surface of the reflection-enhancing film 71 are coherent and constructively interfere, and the light waves mutually superpose, thereby increasing the energy of the light reflected by the reflection-enhancing film, and increasing the reflectivity of the light reflected by the reflection-enhancing film 71, thereby reducing the intensity of light irradiating the active layer 40 and reducing the impact of light on the thin film transistor.

Specifically, in this embodiment, a material of the first reflection-enhancing layer 711 includes but is not limited to one of titanium dioxide (TiO₂) or zinc sulfide (ZnS), and a material of the second reflection-enhancing layer 712 includes but is not limited to one of silicon dioxide (SiO₂), copper sulfide (CuS), or magnesium fluoride (MgF₂).

In this embodiment, the technical solution of the present application is illustrated in an example where the refractive index n₂ of the substrate 10 is 1.5. The material of the first reflection-enhancing layer 711 is titanium dioxide, and the refractive index n_{H} of the first reflection-enhancing layer 711 is 2.55. The material of the second reflection-enhancing layer 712 is silicon dioxide, the refractive index n_{L} of the second reflection-enhancing layer 712 is 1.6, and the wavelength λ of the incident light ranges from 380 nanometers to 780 nanometers.

In this embodiment, it is to be noted that when the light is incident from the denser medium to the less dense medium, according to the following relational equation satisfied by the thickness of the first reflection-enhancing layer 711 and the wavelength λ of the incident light: 2n_{H}h₁+λ/2=kλ. When k=1, the thickness of the first reflection-enhancing layer 711 is in a range of 37 nanometers to 76 nanometers. Similarly, according to the following relational equation satisfied by the thickness of the second reflection-enhancing layer 712 and the wavelength λ of the incident light: 2n_{L}h₁+λ/2=kλ. When k=1, the thickness of the second reflection-enhancing layer 712 is in a range of 59 nanometers to 121 nanometers. It should be noted that n_{L} is the refractive index of the second reflection-enhancing layer 712. This embodiment does not specifically limit the value of the refractive index n of the second reflection-enhancing layer 712.

Following the above, in this embodiment, the amplitude A of the incident light, the amplitude A1′ of the reflected light on the upper surface of the reflection-enhancing film 71, the amplitude A2′ of the reflected light on the lower surface of the reflection-enhancing film 71, the intensity I of the reflected light and the refractive index n₂ of the substrate 10 satisfy the following equation:

$${A}_{1}^{‵} = \vert \frac{{n}_{2} - {n}_{1}}{{n}_{2} + {n}_{1}} \vert {A}_{1} \qquad ( 2 )$$

$${A}_{2}^{‵} = ( \frac{4 {n}_{2} {n}_{1}}{{( {n}_{2} + {n}_{1} )}^{2}} + 1 ) \vert \frac{{n}_{2} - {n}_{1}}{{n}_{2} + {n}_{1}} \vert {A}_{1} \qquad ( 3 )$$

$${I}^{‵} = {( {A}_{1}^{‵} + {A}_{2}^{‵} )}^{2} \qquad ( 4 )$$

When the refractive index n₂ of the substrate 10 is 1.5 and the refractive index n_{H} of the first reflection-enhancing layer 711 is 2.55, Γ=0.251A₁ is obtained from the above equation. That means, in this embodiment, the reflectivity R₀ of the reflection-enhancing film 71 is 25.1%. Since the reflection-enhancing film group 70 includes one reflection-enhancing film 71 in this embodiment, the reflectivity R₀ of the reflection-enhancing film 71 is the refractive index of the reflection-enhancing film 71.

It should be noted that the reflection-enhancing film 71 including one first reflection-enhancing layer 711 and one second reflection-enhancing layer 712 is used for illustration only. For example, in another embodiment as shown in FIG. 3, the reflection-enhancing films 71 include a plurality of first reflection-enhancing layers and a plurality of second reflection-enhancing layers 711. The plurality of first reflection-enhancing layers and the plurality of second reflection-enhancing layers 712 are alternately disposed along the direction of the substrate 10 toward the active layer 40. This embodiment only illustrates the technical solution of the present application with the example that the reflection-enhancing film 71 includes the plurality of first reflection-enhancing layers 711 and the plurality of second reflection-enhancing layers 712.

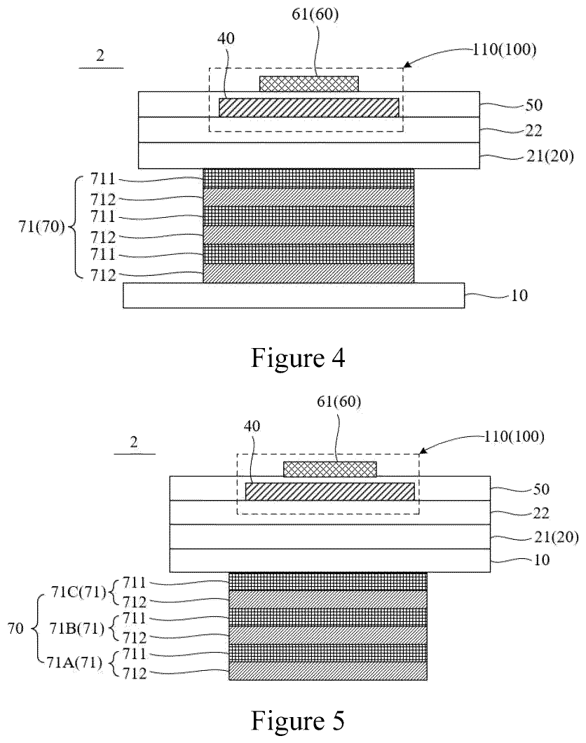

Please refer to FIG. 4, which is a schematic diagram showing a third structure of a display panel provided by an embodiment of the present application;

In this embodiment, the structure of the display panel is similar/identical to the first structure of the display panel provided in the above embodiment. With that regard, please refer to the description of the display panel in the above embodiment, which will not be described again here. The differences between the structures are only as follows:

In this embodiment, the reflection-enhancing film group 70 includes a plurality of reflection-enhancing films 71. The plurality of reflection-enhancing layers 710 are stacked on the substrate 10 in a direction from the substrate 10 toward the active layer 40, where one of the reflection-enhancing films 71 includes a first reflection-enhancing layer 711 and a second reflection-enhancing layer 712, and a first reflection-enhancing film 71A is located on a side of a second reflection-enhancing film 71B away from the substrate 10.

In this embodiment, the refractive indexes n_{H} of the first reflection-enhancing layers 711 located in different layers are the same or different, and/or the refractive indexes n of the second reflection-enhancing layers located in different layers is the same or different. Preferably, the refractive indexes n_{H} of the first reflection-enhancing layers located in different layers are the same, and the refractive indexes n_{L} of the second reflection-enhancing layers located in different layers are the same. Specifically, the refractive index n_{L} of any second reflection-enhancing layer 712 is less than the refractive index n_{H} of the first reflection-enhancing layer 711 in contact with either side of that second reflection-enhancing layer 712.

It can be understood that, in this embodiment, the reflection-enhancing film group 70 includes a plurality of reflection-enhancing films 71, and the plurality of reflection-enhancing layers 710 are stacked on the substrate 10 in the direction from the substrate 10 toward the active layer 40. The refractive index n_{L} of the second reflection-enhancing layer 712 is less than the refractive index n_{H} of the first reflection-enhancing layer 711 in contact with either side of the second reflection-enhancing layer 712, thereby increasing the energy of the light reflected by the reflection-enhancing films 71, and increasing the reflectivity of the light reflected by the reflection-enhancing films 71, thereby reducing the intensity of light irradiating the active layer 40 and reducing the impact of light on the thin film transistor.

In this embodiment, the refractive index of the reflection-enhancing film group 70, the refractive indexes of the first reflection-enhancing layers 711, and the refractive indexes of the second reflection-enhancing layers 712 satisfy the following equation:

$${R}_{1} = {( \frac{{n}_{0} - {( {n}_{H} / {n}_{L} )}^{2 k} ( {n}_{H}^{2} / {n}_{2} )}{{n}_{0} - {( {n}_{H} / {n}_{L} )}^{2 k} ( {n}_{H}^{2} / {n}_{2} )} )}^{2} \qquad ( 5 )$$

where R₁ is the refractive index of the reflection-enhancing film group 70, no is the refractive index of air, n_{H} is the refractive index of the first reflection-enhancing layers 711, n_{L} is the refractive index of the second reflection-enhancing layers 712, n₂ is the refractive index of the substrate 10, 2 k is the total number of layers of the reflection-enhancing layers 710, and k is a natural number.

It can be seen from the above equation that, in this embodiment, when the greater the number of layers of the reflection-enhancing films 71 in the reflection-enhancing film group 70 is, and the greater the difference between the refractive index n_{H} of the first reflection-enhancing layer 711 and the refractive index n_{L} of the second reflection-enhancing layer 712 is, the reflectivity R₁ of the reflection-enhancing film group 70 will be further increased. That means, under the condition that the above equation is satisfied, in this embodiment the reflectivity R₁ of the reflection-enhancing film 71 can be controlled by control of the number of layers of the reflection-enhancing films 71 in the reflection-enhancing film group 70 and control of the difference between the refractive index n_{H} of the first reflection-enhancing layers 711 and the refractive index n_{L} of the second reflection-enhancing layers 712, so as to control the reflectivity R₁ of the reflection-enhancing films 71.

Further, in this embodiment, the reflection-enhancing film group 70 includes a first reflection-enhancing film 71A, a second reflection-enhancing film 71B, and a third reflection-enhancing film 71C, which are stacked on the substrate 10. The first reflection-enhancing film 71A reflects a first color light, the second reflection-enhancing film 71B reflects a second color light, and the third reflection-enhancing film 71C reflects a third color light, where the color of the first color light, the color of the second color light, and the color of the third color light are all different. Preferably, the first color light is blue light, the second color light is green light, and the third color light is red light.

Specifically, in this embodiment, the refractive index n₂ of the substrate 10 is 1.5, the refractive index n_{H} of the first reflection-enhancing layers 711 is 2.55, and the refractive index n_{L} of the second reflection-enhancing layers 712 is 1.6. The wavelength range of the first color light is 380 nanometers to 450 nanometers, the wavelength range of the second color light is 450 nanometers to 570 nanometers, and the wavelength range of the third color light is 570 nanometers to 780 nanometers, which are taken as an example to illustrate the technical solution of the present application.

According to the above equation (1), the thickness of the first reflection-enhancing layer 711 in the first reflection-enhancing film 71A ranges from 37 nanometers to 44 nanometers, and the thickness of the second reflection-enhancing layer 712 in the first reflection-enhancing film 71A ranges from 59 nanometers to 70 nanometers. The thickness of the first reflection-enhancing layer 711 in the second reflection-enhancing film 71B ranges from 44 nanometers to 56 nanometers, and the thickness of the second reflection-enhancing layer 712 in the second reflection-enhancing film 71B ranges from 70 nanometers to 89 nanometers. The thickness of the first reflection-enhancing layer 711 in the first reflection-enhancing film 711 in the third reflection-enhancing film 71C ranges from 56 nanometers to 76 nanometers, and the thickness of the second reflection-enhancing layer 712 in the third reflection-enhancing film 71C ranges from 89 nanometers to 121 nanometers. It should be noted that this embodiment does not specifically limit the value of the refractive index n_{L} of the second reflection-enhancing layer 712.

Further, in this embodiment, the calculation formula for the reflectivity of the six layers of the reflection-enhancing layer 710 is:

$${R}_{1} = {( \frac{{n}_{2} - {n}_{H}^{6} / {n}_{2}^{5}}{{n}_{2} + {n}_{H}^{6} / {n}_{2}^{5}} )}^{2} \qquad ( 6 )$$

where R₁ is the reflectivity of the reflection-enhancing film group 70, n₂ is the refractive index of the substrate 10, and n_{H} is the refractive index of the first reflection-enhancing layer 711.

When the refractive index n₂ of the substrate 10 is 1.5 and the refractive index n_{H} of the first reflection-enhancing layer 711 is 2.55, a result R₁-84.7% is obtained from the above relational equation (6). That means, in this embodiment, the reflectivity of the reflection-enhancing film group 70 can reach 84.7%.

It should be noted that the refractive index n_{H} of the first reflection-enhancing layer 711 being 2.55 is for illustration only. For example, in another embodiment where the material of the first reflection-enhancing layer 711 is zinc sulfide and the refractive index n_{H} of the first reflection-enhancing layer 711 is 2.4, when the refractive index n₂ of the substrate 10 is 1.5 and the refractive index n_{H} of the first reflection-enhancing layer 711 is 2.4, a result R₁=88.7% is obtained from the above relational equation (6). That means, in this embodiment, the reflectivity of the reflection-enhancing film group 70 can reach 88.7%.

Please refer to FIG. 5, which is a schematic diagram showing a fourth structure of a display panel provided by an embodiment of the present application.

In this embodiment, the structure of the display panel is similar/identical to the second structure of the display panel provided in the above embodiment. With that regard, please refer to the description of the display panel in the above embodiment, which will not be described again here. The differences between the two structures are only as follows:

In this embodiment, the reflection-enhancing film group 70 is located on a side of the substrate 10 away from the buffer layer 20. The reflection-enhancing film 71 includes first reflection-enhancing layers 711 and second reflection-enhancing layers 712. The refractive index n_{H} of the first reflection-enhancing layers 711 is greater than the refractive index n_{L} of the second reflection-enhancing layers 712. The reflection-enhancing layer 711 is located on a side of the second reflection-enhancing layer 712 close to the substrate 10.

It can be understood that this embodiment reduces the manufacturing process cost of the display panel 2 by arranging the reflection-enhancing film group 70 on the side of the substrate 10 away from the buffer layer 20.

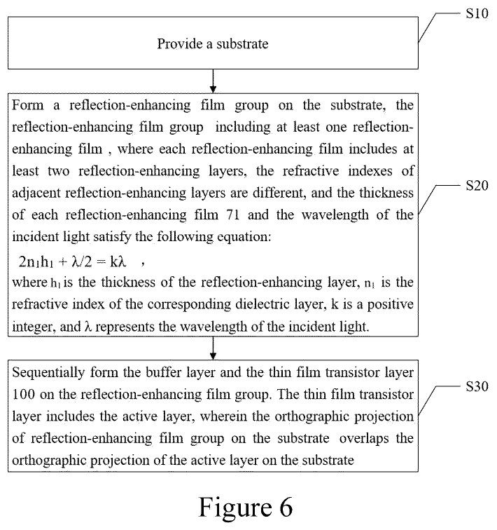

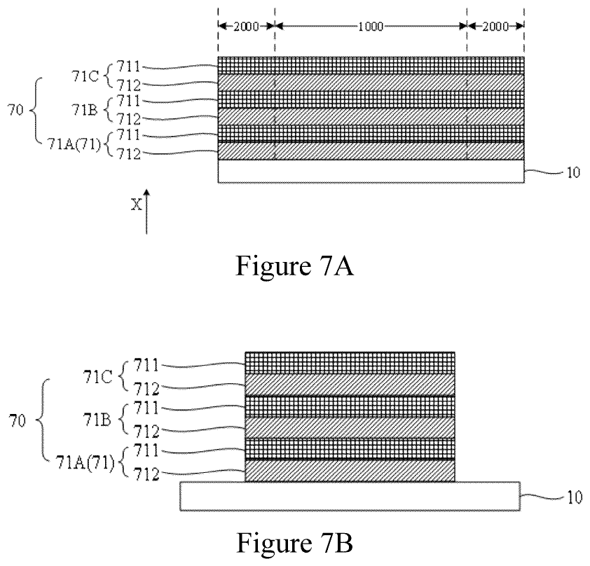

In an embodiment it also provides a method for manufacturing a display panel. Please refer to FIG. 3, FIG. 6, FIG. 7A, and FIG. 7B, where FIG. 6 is a flow chart of a manufacturing method of a display panel provided by the embodiments of the present application, and FIGS. 7A to 7B are structural process flow diagrams showing the manufacturing of the display panel in FIG. 6.

In this embodiment, the manufacturing method of the display panel 2 includes the following steps:

Step S10: Provide a substrate 10.

Step S20: Form a reflection-enhancing film group 70 on the substrate 10, the reflection-enhancing film group 70 including at least one reflection-enhancing film 71, where the reflection-enhancing film 71 includes at least two reflection-enhancing layers 710, the refractive indexes of adjacent reflection-enhancing layers 710 are different, and the thickness of the reflection-enhancing film 71 and the wavelength of the incident light satisfy the following equation:

$$2 {n}_{1} {h}_{1} + λ / 2 = k λ ,$$

where h₁ is the thickness of the reflection-enhancing layer 710, n₁ is the refractive index of the corresponding dielectric layer, k is a positive integer, and λ represents the wavelength of the incident light.

Specifically, in this embodiment, step S20 includes:

Step S21: Form a plurality of first reflection-enhancing layers 711 and a plurality of second reflection-enhancing layers 712 on the substrate 10, wherein the plurality of first reflection-enhancing layers and the plurality of second reflection-enhancing layers are alternately disposed along a first direction X, where the refractive index n_{H} of the first reflection-enhancing layers 711 is greater than the refractive index n of the second reflection-enhancing layers 712, and the first reflection-enhancing layers 711 are located on the side of the second reflection-enhancing layers 712 away from the substrate 10, as shown in FIG. 7A.

It should be noted that in this embodiment, the first direction is not limited, but for convenience of description. In this embodiment, the first direction is exemplarily taken as the direction X to illustrate the technical solution of the present application.

Step S22: The reflection-enhancing film group 70 includes a light-shielding area 1000 and a waste area 2000. The reflection-enhancing film group 70 is patterned to remove the reflection-enhancing film group 70 located in the waste area 2000, as shown in FIG. 7B.

Step S30: Sequentially form the buffer layer 20 and the thin film transistor layer 100 on the reflection-enhancing film group 70. The thin film transistor layer 100 includes an active layer 40, where the orthographic projection of the reflection-enhancing film group 70 on the substrate 10 overlaps the orthographic projection of the active layer 40 on the substrate 10, as shown in FIG. 3.

It can be understood that, in this embodiment, the reflection-enhancing film group 70 is located on the side of the buffer layer 20 away from the active layer 40, and the orthographic projection of the reflection-enhancing film group 70 on the substrate 10 overlaps the orthographic projection of the active layer 40 on the substrate 10. The reflection-enhancing film group 70 includes at least one reflection-enhancing film 71, the reflection-enhancing film 71 includes at least two reflection-enhancing layers 710, and the refractive indexes of adjacent reflection-enhancing layers 710 are different. By using the reflection-enhancing film group 70 to replace the metal light-shielding layer 30 in the prior art, the problem of electrostatic discharge (ESD) in existing display panels caused by the “metal light-shielding layer 30” may be avoided.

Another embodiment provides a display device, which includes the display panel described in any of the above embodiments.

It can be understood that the display panel has been described in detail in the above embodiments, and the description thereof will not be repeated here.

In specific applications, the display device can be the display screen of a device such as a smart phone, a tablet computer, a notebook computer, a smart bracelet, a smart watch, a smart glass, a smart helmet, a desktop computer, a smart TV or a digital camera, and can even be applied to an electronic device with a flexible display screen.

To sum up, although the present application has been disclosed as above with various example embodiments, the above example embodiments are not used to limit the present invention, and a person skilled in the art can make various changes and modification without departing from the spirit and scope of the present invention, so the scope of protection of the present application is subject to the scope defined by the claims.

1. A display panel, comprising:
a substrate;
a buffer layer located above the substrate;
a thin film transistor layer located on one side of the buffer layer away from the substrate, wherein the thin film transistor layer includes an active layer;
a reflection-enhancing film group located on one side of the buffer layer away from the active layer, wherein an orthographic projection of the reflection-enhancing film group on the substrate overlaps an orthographic projection of the active layer on the substrate, the reflection-enhancing film group includes one or more reflection-enhancing films, each reflection-enhancing film includes at least two reflection-enhancing layers, and a refractive index of a first reflection-enhancing layers away from the substrate is greater than a refractive index of a second reflection-enhancing layers close to the substrate;
wherein, a thickness of each reflection-enhancing layer and a wavelength of incident light satisfy the following equation:
$$2 {n}_{1} {h}_{1} + λ / 2 = k λ$$
where h₁ is the thickness of the reflection-enhancing layer, n₁ is a refractive index of a corresponding dielectric layer of the reflection-enhancing layer, k is a positive integer, and λ represents the wavelength of the incident light.

2. The display panel of claim 1, wherein the reflection-enhancing films included in the reflection-enhancing film group are stacked.

3. The display panel of claim 1, wherein each reflection-enhancing film includes a plurality of first reflection-enhancing layers and a plurality of second reflection-enhancing layers, and the plurality of first reflection-enhancing layers and the plurality of second reflection-enhancing layers are alternately disposed along a direction from the substrate toward the active layer.

4. The display panel of claim 3, wherein refractive indexes of the first reflection-enhancing layers located in different layers are the same or different, and/or refractive indexes of the second reflection-enhancing layers located in different layers are the same or different.

5. The display panel of claim 4, wherein the refractive index of any one second reflection-enhancing layer of the plurality of second reflection-enhancing layers is less than the refractive index of a first reflection-enhancing layer that is in contact with either side of the second reflection-enhancing layer among of the plurality of first reflection-enhancing layers.

6. The display panel of claim 1, wherein the reflection-enhancing film group is located between the substrate and the buffer layer, and the reflection-enhancing films included in the reflection-enhancing film group are a first reflection-enhancing film, a second reflection-enhancing film, and a third reflection-enhancing film, wherein the first reflection-enhancing film reflects first color light, the second reflection-enhancing film reflects second color light, and the third reflection-enhancing film reflects third color light; and
wherein a color of the first color light, a color of the second color light, and a color of the third color light are all different.

7. The display panel of claim 6, wherein the first color light is blue light, the second color light is green light, and the third color light is red light; and
the thickness of the first reflection-enhancing layer of the first reflection-enhancing film ranges from 37 nanometers to 44 nanometers, and the thickness of the second reflection-enhancing layer of the first reflection-enhancing film ranges from 59 nanometers to 70 nanometers; the thickness of the first reflection-enhancing layer of the second reflection-enhancing film ranges from 44 nanometers to 56 nanometers, and the thickness of the second reflection-enhancing layer of the second reflection-enhancing film ranges from 70 nanometers to 89 nanometers; and the thickness of the first reflection-enhancing layer of the third reflection-enhancing film ranges from 56 nanometers to 76 nanometers, and the thickness of the second reflection-enhancing layer of the third reflection-enhancing film ranges from 89 nanometers to 121 nanometers.

8. The display panel of claim 7, wherein a reflectivity of the reflection-enhancing film group, a refractive index of the first reflection-enhancing layers, and a refractive index of the second reflection-enhancing layers satisfy the following equation:
$${R}_{1} = {( \frac{{n}_{0} - {( {n}_{H} / {n}_{L} )}^{2 k} ( {n}_{H}^{2} / {n}_{2} )}{{n}_{0} - {( {n}_{H} / {n}_{L} )}^{2 k} ( {n}_{H}^{2} / {n}_{2} )} )}^{2}$$
where R₁ is the reflectivity of the reflection-enhancing film group, n₀ is refractive index of air, n_{H} is the refractive index of the first reflection-enhancing layers, n_{L} is the refractive index of the second reflection-enhancing layers, n₂ is a refractive index of the substrate, 2 k is a total number of layers of the reflection-enhancing layers, and k is a natural number.

9. The display panel of claim 1, wherein the reflection-enhancing film group is located on one side of the substrate away from the buffer layer.

10. The display panel of claim 1, wherein a material of each reflection-enhancing film is one of titanium dioxide or zinc sulfide.

11. A display panel, comprising:
a substrate;
a buffer layer located above the substrate;
a thin film transistor layer located on one side of the buffer layer away from the substrate, wherein the thin film transistor layer includes an active layer;
a reflection-enhancing film group located on one side of the buffer layer away from the active layer, wherein an orthographic projection of the reflection-enhancing film group on the substrate overlaps an orthographic projection of the active layer on the substrate, the reflection-enhancing film group includes one or more reflection-enhancing films, each reflection-enhancing film includes at least two reflection-enhancing layers, and a refractive index of a first reflection-enhancing layers away from the substrate is greater than a refractive index of a second reflection-enhancing layers close to the substrate;
wherein, a thickness of each reflection-enhancing layer and a wavelength of incident light satisfy the following equation:
$$2 {n}_{1} {h}_{1} + λ / 2 = k λ$$
where h₁ is the thickness of the reflection-enhancing layer, n₁ is a refractive index of a corresponding dielectric layer of the reflection-enhancing layer, k is a positive integer, and λ represents the wavelength of the incident light.

12. The display device of claim 11, wherein the reflection-enhancing films included in the reflection-enhancing film group are stacked.

13. The display device of claim 11, wherein each reflection-enhancing film includes a plurality of first reflection-enhancing layers and a plurality of second reflection-enhancing layers, and the plurality of first reflection-enhancing layers and the plurality of second reflection-enhancing layers are alternately disposed along a direction from the substrate toward the active layer.

14. The display device of claim 13, wherein refractive indexes of the first reflection-enhancing layers located in different layers are the same or different, and/or refractive indexes of the second reflection-enhancing layers located in different layers are the same or different.

15. The display panel of claim 14, wherein the refractive index of any one second reflection-enhancing layer of the plurality of second reflection-enhancing layers is less than the refractive index of a first reflection-enhancing layer that is in contact with either side of the second reflection-enhancing layer among of the plurality of first reflection-enhancing layers.

16. The display device of claim 11, wherein the reflection-enhancing film group is located between the substrate and the buffer layer, and the reflection-enhancing films included in the reflection-enhancing film group are a first reflection-enhancing film, a second reflection-enhancing film, and a third reflection-enhancing film, wherein the first reflection-enhancing film reflects first color light, the second reflection-enhancing film reflects second color light, and the third reflection-enhancing film reflects third color light; and
wherein a color of the first color light, a color of the second color light, and a color of the third color light are all different.

17. The display device of claim 16, wherein the first color light is blue light, the second color light is green light, and the third color light is red light; and
the thickness of the first reflection-enhancing layer of the first reflection-enhancing film ranges from 37 nanometers to 44 nanometers, and the thickness of the second reflection-enhancing layer of the first reflection-enhancing film ranges from 59 nanometers to 70 nanometers; the thickness of the first reflection-enhancing layer of the second reflection-enhancing film ranges from 44 nanometers to 56 nanometers, and the thickness of the second reflection-enhancing layer of the second reflection-enhancing film ranges from 70 nanometers to 89 nanometers; and the thickness of the first reflection-enhancing layer of the third reflection-enhancing film ranges from 56 nanometers to 76 nanometers, and the thickness of the second reflection-enhancing layer of the third reflection-enhancing film ranges from 89 nanometers to 121 nanometers.

18. The display device of claim 17, wherein a reflectivity of the reflection-enhancing film group, a refractive index of the first reflection-enhancing layers, and a refractive index of the second reflection-enhancing layers satisfy the following equation:
$${R}_{1} = {( \frac{{n}_{0} - {( {n}_{H} / {n}_{L} )}^{2 k} ( {n}_{H}^{2} / {n}_{2} )}{{n}_{0} - {( {n}_{H} / {n}_{L} )}^{2 k} ( {n}_{H}^{2} / {n}_{2} )} )}^{2}$$
where R₁ is the reflectivity of the reflection-enhancing film group, n₀ is refractive index of air, n_{H} is the refractive index of the first reflection-enhancing layers, n_{L} is the refractive index of the second reflection-enhancing layers, n₂ is refractive index of the substrate, 2 k is a total number of layers of the reflection-enhancing layers, and k is a natural number.

19. The display device of claim 11, wherein the reflection-enhancing film group is located on one side of the substrate away from the buffer layer.

20. The display device of claim 11, wherein a material of each reflection-enhancing film is one of titanium dioxide or zinc sulfide.
